(19) United States
(12) Patent Application Publication
(10) Pub. No.: US 2009/0032939 A1
(43) Pub. Date: Feb. 5, 2009

(54) METHOD OF FORMING A STUD BUMP OVER PASSIVATION, AND RELATED DEVICE

(75) Inventors: Peter R. HARPER, Lucas, TX (US); Thomas E. MARCHAND-GOLDER, Villeneuve-Loubet (FR)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/831,068

(22) Filed: Jul. 31, 2007

(51) Int. Cl. H01L 23/48; H01L 21/44

(52) U.S. Cl. 257/737; 438/614; 257/E23.021; 257/E21.582

(57) ABSTRACT

A method of forming a stud bump over passivation, and related device. At least some of the illustrative embodiments are methods comprising depositing a first passivation layer over a semiconductor die, depositing a capping metal layer over the first passivation layer (the capping metal layer comprises a capping metal pad), and depositing a stud bump onto the capping metal pad.

### BACKGROUND

Electronic devices are continually getting smaller, faster, and using less power, while simultaneously being able to support and perform a greater number of increasingly complex and sophisticated functions. One reason for these trends is an ever increasing demand for small, portable and multifunctional electronic devices. For example, cellular phones, personal computing devices, and personal audio devices (e.g., MP3 players) are in great demand in the consumer market. Such electronic devices rely on a limited power source (e.g., batteries) while providing ever-increasing processing capabilities and storage capacity.

Accordingly, there is a continuing trend in the semiconductor industry to manufacture low-cost, high-performance, and low-power integrated circuits (ICs). IC manufacturing involves a series of processing steps such as transistor fabrication, fabrication of interconnect layers, testing to check for defects in the IC, and packaging of individual die (i.e., “chips”). IC packages serve a multitude of functions such as providing mechanical stability, providing for electrical communication with external circuitry and components, providing power to the die, and drawing heat away from the die. Thus packaging technology, including the method of electrically coupling the die to the package, should meet the demands imposed by the continued advances in IC design and manufacturing.

### SUMMARY

The problems noted above are solved in large part by a method of forming a stud bump over passivation, and related device. At least some of the illustrative embodiments are methods comprising depositing a first passivation layer over a semiconductor die, depositing a capping metal layer over the first passivation layer (the capping metal layer comprises a capping metal pad), and depositing a stud bump onto the capping metal pad.

Other illustrative embodiments are semiconductor devices comprising a first passivation layer, a capping metal layer on the first passivation layer (the capping metal layer comprising a capping metal pad), and a stud bump on the capping metal pad.

### BRIEF DESCRIPTION OF THE DRAWINGS

For a more detailed description of the various embodiments, reference will now be made to the accompanying drawings, wherein:

FIG. 1 shows a flip chip ball grid array assembly;

FIG. 2A shows a bond pad;

FIG. 2B shows a die having a pad ring;

FIG. 3 shows a semiconductor device according to some embodiments;

FIG. 4 shows a layout schematic of a metal routing scheme according to some embodiments;

FIG. 5 shows a layout schematic of a top view of a capping metal pad according to some embodiments; and

FIG. 6 shows an exemplary flow diagram according to some embodiments.

### NOTATION AND NOMENCLATURE

Certain terms are used throughout the following description and claims to refer to particular system components. As one skilled in the art will appreciate, various companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the term “couple” or “couples” is intended to mean either an indirect or direct connection. Thus, if a first device couples to a second device, that connection may be through a direct connection, or through an indirect connection via other devices and connections.

The term “active area” means a region where a semiconductor device is formed within and/or on a semiconductor substrate. Unless otherwise stated, when a layer is said to be “deposited over” or “formed over”, it means that the layer is deposited or formed over any topography that already exists on the substrate.

### DETAILED DESCRIPTION

The following discussion is directed to various embodiments. Although one or more of these embodiments may be preferred, the embodiments disclosed should not be interpreted, or otherwise used, as limiting the scope of the disclosure, including the claims, unless otherwise specified. In addition, one skilled in the art will understand that the following description has broad application, and the discussion of any embodiment is meant only to be exemplary of that embodiment, and not intended to intimate that the scope of the disclosure, including the claims, is limited to that embodiment. Also, layers and/or elements depicted herein are illustrated with particular dimensions and/or orientations relative to one another for purposes of simplicity and ease of understanding, and actual dimensions and/or orientations of the layers and/or elements may differ substantially from that illustrated herein.

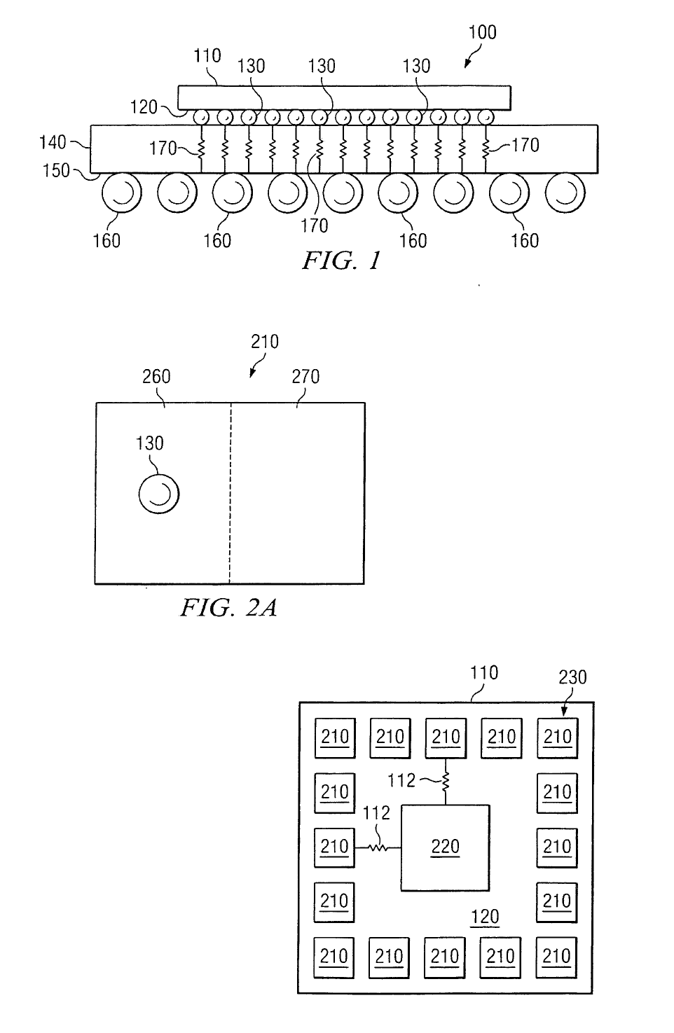

The subject matter disclosed herein is directed to methods associated with construction of a semiconductor device that utilizes stud bump flip chip packaging design. In particular, the subject matter disclosed herein is directed to methods and related systems associated with power distribution on a semiconductor die that utilizes such a packaging design. In some embodiments, the methods and related systems described herein may also be applied to distribution of input/output (I/O) signals, or other signals, throughout the semiconductor die. FIG. 1 illustrates an example of a flip chip ball grid array (BGA) assembly 100 where a die 110 is electrically coupled (in a “face-down” manner) to a substrate 140 by way of a plurality of electrically conductive bumps 130, where one of the plurality of electrically conductive bumps 130 is deposited onto one of a plurality of bond pads disposed along a periphery of a front side 120 of the die 110. FIG. 2A illustrates a top view of an exemplary bond pad 210 upon which a bump 130 is deposited. Each bond pad 210 comprises a bump region 260, where the electrically conductive bump 130 is deposited and a probe region 270, where in-line electrical testing is performed. In some embodiments, the bond pad 210 need not comprise the probe region 270. In other embodiments, the bond pad 210 need not comprise the bump region 260. In yet still other embodiments, a plurality of bumps 130 may be deposited on a single bond pad 210.

Returning to FIG. 1, a plurality of BGA balls 160 are attached to a side 150 of the substrate 140, and the substrate 140 has internal conductive traces 170 used to route and electrically couple the bumps 130 to the BGA balls 160. While one may employ a 1:1 bump-to-BGA ball ratio for power supplies (e.g., Vdd), in some embodiments (discussed below) the bump-to-BGA ratio is increased in order to save BGA balls for other uses (e.g., other I/O connections). The assembly 100 can then be electrically coupled to a circuit board or other packaging by way of the BGA balls 160.

Flip chip technology (with or without BGA) results in reduced cost, reduced package size (e.g., as compared to packaging utilizing wire bonding), and offers superior performance compared to older technologies (e.g., wire bonding). As shown in FIG. 2B, however, flip chip power and I/O connections are in some cases restricted to bond pads 210 along a pad ring 230 situated along the periphery of the die 110. In cases where bond pads 210 are limited to a pad ring 230, power and I/O signals are routed to a die core area 220 from the bond pads 210 by way of conductive traces, such as exemplary conductive traces 112. Such chip design results in longer current conduction paths (e.g., in routing power from the bond pads 210 to the die core area 220 via conductive traces 112), which results in increased resistance, undesirable voltage (i.e., IR) drops, increased inductance, and poor electromigration characteristics, among others. The various embodiments described herein provide a method, and related structure, where the bumps 130 (FIG. 1) are placed over a passivation layer with no direct underlying connection to the chip active area. In particular, in the present embodiments, the bumps 130 (FIG. 1) can be placed freely throughout the die 110 for efficient power distribution resulting from shortened current conduction paths.

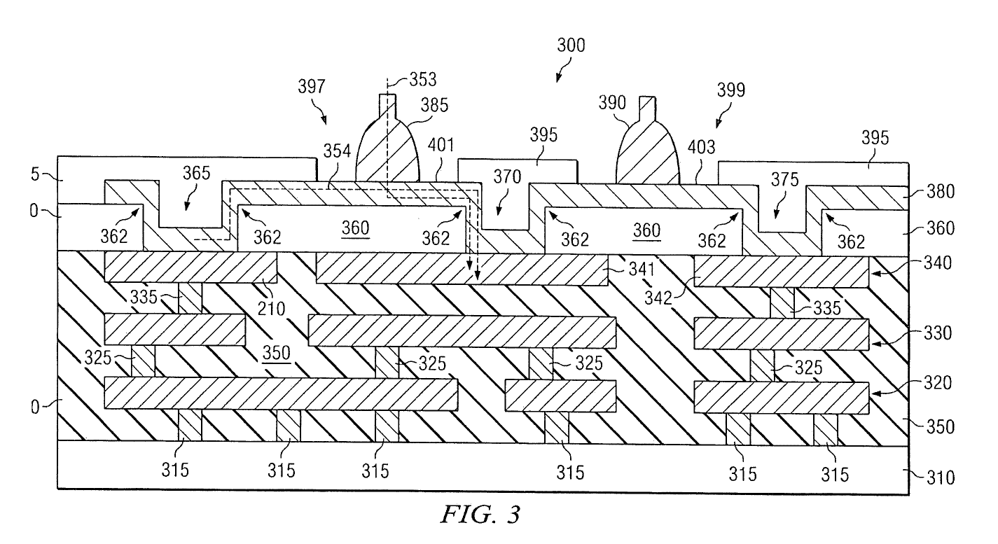

FIG. 3 illustrates a semiconductor device 300 according to some exemplary embodiments. The semiconductor device 300 can be fabricated through a series of semiconductor processing techniques (e.g., deposition, photolithography, etching, ion implantation). The semiconductor device 300 comprises an active area 310 (lower right) where devices (e.g., transistors, resistors, capacitors, etc.) are formed within and/or on a semiconductor substrate. In some embodiments, the active area 310 comprises a P-type single crystal silicon substrate that may be formed, for example, by epitaxial growth. In other embodiments, the active area 310 comprises a silicon germanium (SiGe) substrate or a silicon-on-insulator (SOI) substrate. After processing of the active area 310, metal interconnect layers 320, 330, 340 are deposited, patterned, and etched. Metal layers 320, 330, 340 are exemplary, and in other embodiments, there may be more or less metal interconnect layers. Metal interconnect layers 320, 330, 340 are used for routing signals (e.g., power, ground, I/O signals, etc.) throughout the semiconductor device 300 (e.g., to various devices within the active area 310 and across the die 110 (FIG. 2B)), and the metal interconnect layers may be formed from a variety of conductive materials such as copper or aluminum, among others. Metal layer 320 electrically couples to the active area 310 by way of contacts 315, metal layer 330 electrically couples to metal layer 320 by way of vias 325, and metal layer 340 electrically couples to metal layer 330 by way of vias 335. Metal layer 340 may be equivalently referred to as a top metal layer 340.

The top metal layer 340 also comprises the bond pad 210, top metal routing 341, and top metal routing 342. The bond pad 210 may be equivalently referred to as a top metal pad 210. Top metal routings 341, 342 may be used as part of, for example, a power distribution grid used to route power throughout the die 110 (FIG. 2B). A dielectric 350 comprising a non-conductive material (e.g., a low dielectric constant (“low-K”) material) is used to insulate the metal interconnect layers 320, 330, 340 from each other (e.g., to prevent cross-talk). In some embodiments, the dielectric 350 comprises a plurality of dielectric layers.

After formation of the top metal layer 340, a first passivation layer 360 is deposited over the top metal layer 340. In some embodiments, the first passivation layer 360 comprises a non-conductive material such as a nitride (e.g., silicon nitride) or an oxide (e.g., silicon dioxide). Vias 365, 370, 375 are formed within the first passivation layer 360, and a metal layer 380 is deposited over the first passivation layer 360. Metal layer 380 may be equivalently referred to as a capping metal layer 380. The capping metal layer 380 is deposited, patterned, and etched to form a particular metal routing over particular portions of the die 110 (FIG. 2B) upon which bumps can be placed (discussed below). In some instances, via 365 may be wider than vias 370, 375 in order to accommodate the top metal pad 210 (i.e., the bond pad 210). The wider via 365 is also used to accommodate an electrically conductive bump (e.g., bump 130 (FIG. 1)). The capping metal layer 380 is deposited such that the capping metal layer 380 is electrically coupled to the top metal pad 210 (by way of the via 365), the top metal routing 341 (by way of the via 370), and the top metal routing 342 (by way of the via 375). In some embodiments, the capping metal layer 380 is used, for example, as part of a power distribution grid that routes power throughout the die 110 (FIG. 2B). In some illustrative embodiments, the capping metal layer 380 is formed from aluminum. A second passivation layer 395 comprising a non-conductive material (such as a nitride (e.g., silicon nitride) or an oxide (e.g., silicon dioxide)) is deposited over the capping metal layer 380 and patterned to form openings 397, 399 in the second passivation layer 395. Electrically conductive bumps 385, 390 are then deposited within the openings 397, 399 directly on the capping metal layer 380. In particular, the bump 385 is deposited on capping metal pad 401, and the bump 390 is deposited on capping metal pad 403. The bumps 385, 390 are thus decoupled from the location of the top metal pad 210. In addition, the bumps 385, 390 are decoupled from the vias 365, 370, 375, since the capping metal layer 380 can be used to route signals from the bumps 385, 390 to appropriate vias, and thus the bumps 385, 390 can be freely placed in a manner which reduces IR drop, reduces metal routing, and optimizes performance of the die 110 (FIG. 2B). In some embodiments, the bumps 385, 390 comprise gold stud bumps that may be deposited, for example, by way of a wire bonder.

In designs without a passivation layer (e.g., without the second passivation layer 395), poor step coverage of deposited metal layers (i.e., for example, thinning of the capping metal layer 380 at corners 362) leaves the semiconductor device 300 vulnerable to electromigration effects due to an increased current density present within thin regions of metal (e.g., capping metal layer 380 at corners 362) that are not protected by a passivation layer. While using redundant vias (e.g., between the capping metal layer 380 and the top metal layer 340) is possible as an attempt to reduce electromigration effects, each of the vias still remains unprotected by a passivation layer, and each of the vias may still have poor step coverage and remain susceptible. Furthermore, using redundant vias increases design complexity and consumes valuable real estate on the die 110 (FIG. 2B). Thus, in some embodiments, the vias 365, 370, 375 (and especially the corners 362) are protected by the second passivation layer 395. In particular, any thinning of the capping metal layer 380 that may occur at the corners 362 (e.g., due to poor step coverage) is protected by the second passivation layer 395 and potentially poor electromigration effects are effectively mitigated. In some embodiments, the second passivation layer 395 improves electromigration characteristics by a factor of two.

As discussed above, the bumps 385, 390 are deposited within the openings 397, 399 directly on the capping metal pads 401, 403 of the capping metal layer 380. In some embodiments, a single bump or a plurality of bumps (e.g., for power supplies such as Vss and Vdd) can be deposited along any portion of the power distribution grid formed by the capping metal layer 380 that has the first passivation layer 360 directly beneath the capping metal layer 380. Thus, the placement of the bumps (e.g., bumps 385, 390) is not dependent on the placement of the bond pads 210 (i.e., the top metal pads 210), and the design (e.g., the floorplan) of the die 110 (FIG. 2B) is more flexible. In particular, a bump or plurality of bumps can be placed at any location on the die 110 (FIG. 2B) (e.g., within the die core area 220) for efficient access to the power distribution grid formed by the top metal layer 340.

Illustratively, access to the top metal routing 341 by way of the bump 385 follows a current path indicated by dashed line 353. Alternatively, if bump 385 is deposited within the via 365 (where the top metal pad 210 is directly beneath the capping metal layer 380), access to the top metal routing 341 by way of the bump 385 would follow a current path indicated by dashed line 354. The current path indicated by dashed line 354 comprises two vias (vias 365, 370) and is longer than the current path indicated by dashed line 353 which only comprises via 370. Thus, the current path is shortened and only one via (via 370) is used, resulting in a less resistive current path and lower IR drop between the bump 385 and the top metal routing 341. In some embodiments, reduction in the length of the current path also results in reduced inductance and a corresponding enhancement in performance of the semiconductor device 300. In other embodiments, an electrical connection to the top metal pad 210 (by way of the capping metal layer 380 and the via 365) is retained in order to provide electrostatic discharge (ESD) protection to the semiconductor device 300 by way of an ESD protection cell (not shown) that is electrically coupled to the top metal pad 210 and that is disposed along a periphery of the die 110 (FIG. 2B).

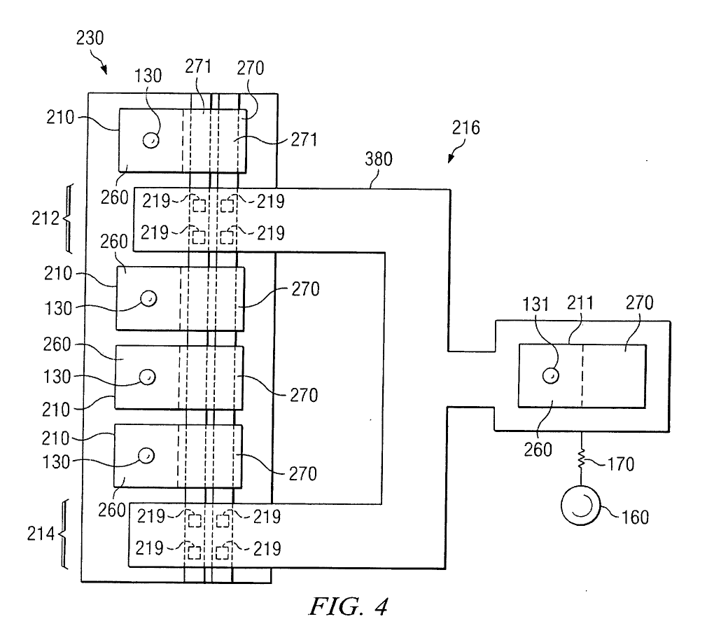

FIG. 4 illustrates a layout schematic of a metal routing scheme used in some embodiments in order to reduce the number of BGA balls 160 used in a given design by consolidation of those BGA balls 160 which are used for equivalent power supply and/or I/O signals. In particular, FIG. 4 shows a portion of the pad ring 230 comprising a plurality of top metal pads 210 each comprising a bump 130. Each of the plurality of top metal pads 210 comprises a bump region 260 and a probe region 270. Furthermore, each of the plurality of top metal pads 210 in the pad ring does not have an underlying passivation layer. An illustrative two bond pads have been removed from the pad ring 230 (at regions 212, 214) and have been replaced with metal routing 216 formed by way of the capping metal layer 380. Thus, the metal routing 216 is part of the power distribution grid formed by the capping metal layer 380. As shown in FIG. 4, the metal routing 216 electrically couples to a capping metal pad 211 which has a bump 131 within a bump region 260, and a probe region 270. The capping metal pad 211, like the capping metal pads 401, 403 (FIG. 3), is distinct from the top metal pads 210 in that the capping metal pad 211 has an underlying passivation layer (i.e., the first passivation layer 360) as illustrated in FIG. 3. Thus, the location of the bump 131 is decoupled from the location of pads in the pad ring 230, as well as from the location of other pads which do not have an underlying passivation layer. A plurality of bumps can therefore be consolidated into a single bump (e.g., bump 131) by way of the metal routing 216. The bump 131 is then electrically coupled to a BGA ball 160 by way of an internal conductive trace 170 within the substrate 140 (FIG. 1). The metal routing 216 also enables the location of the bump 131 to be chosen without regard for the location of the BGA ball 160, resulting in improved flexibility in the placement of the bump 131. Consolidation of top metal pads 210 (e.g., within the pad ring 230) into the capping metal pad 211, and a corresponding consolidation of the bumps 130, enables the bump-to-BGA ball ratio to be increased to reduce a package pin count (i.e., a package ball count), and the conserved BGA balls can be put to other uses (e.g., other power or I/O signals). In some embodiments, the ratio is increased to a 3:1 bump-to-BGA ball ratio. FIG. 4 also illustrates I/O buses 271, formed from the top layer metal 340 (FIG. 3), that electrically couple to the capping metal layer 380 of the metal routing 216 by way of vias 219. In some embodiments, the vias 219 are equivalent to the vias 370, 375 as shown in FIG. 3. In other embodiments, more or less vias 219 may be used in order to meet demands imposed by electromigration characteristics of any particular semiconductor device 300 (FIG. 3).

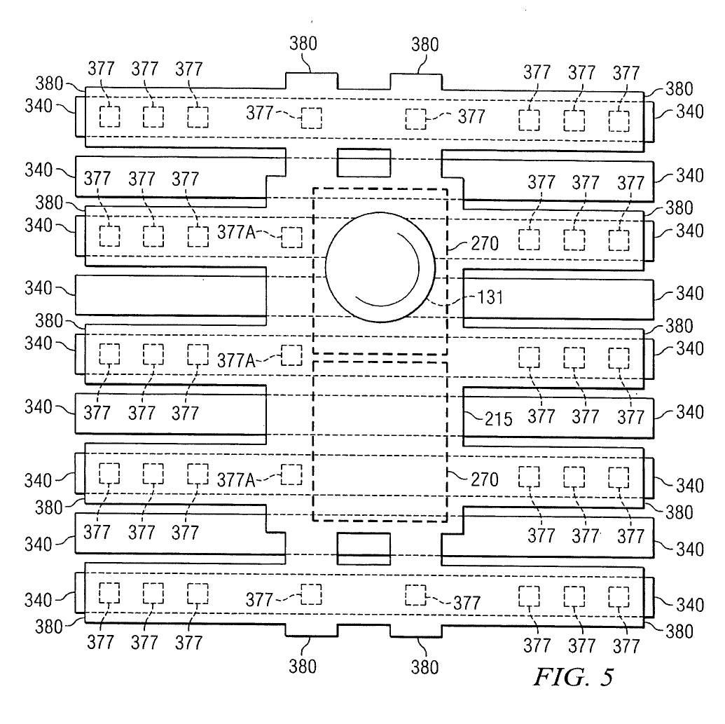

FIG. 5 shows a layout schematic comprising a top view of a capping metal pad 215 having a bump region 260 and a probe region 270. In some embodiments, the capping metal pad 215 is equivalent to the capping metal pad 211 (FIG. 4) or one of the capping metal pads 401, 403 (FIG. 3). Top layer metal 340 forms a first grid used for power distribution, and capping metal layer 380 forms a second grid used for power distribution. Vias 377 are used to electrically couple the first grid to the second grid. A bump 131, placed within the bump region 260, is decoupled from the location of the vias 377 and from the top layer metal 340 which underlies each of the vias 377. The bump 131 can therefore be freely placed anywhere throughout the die 110 (FIG. 2B), and the bump 131 can be electrically coupled to the first grid (and thus power distributed) by way of the vias 377 and the second grid. FIG. 5 also shows optional vias 377A disposed within the capping metal pad 215. In some embodiments, the vias 377A are equivalent to the vias 377. In other embodiments, the vias 377A are covered by the second passivation layer 395 (FIG. 3) to protect against electromigration effects. The addition of the vias 377A also increases a total number of vias (i.e., via count) and thus further protects against electromigration effects. In yet other embodiments, the vias 377 are also covered by the second passivation layer 395 (FIG. 3).

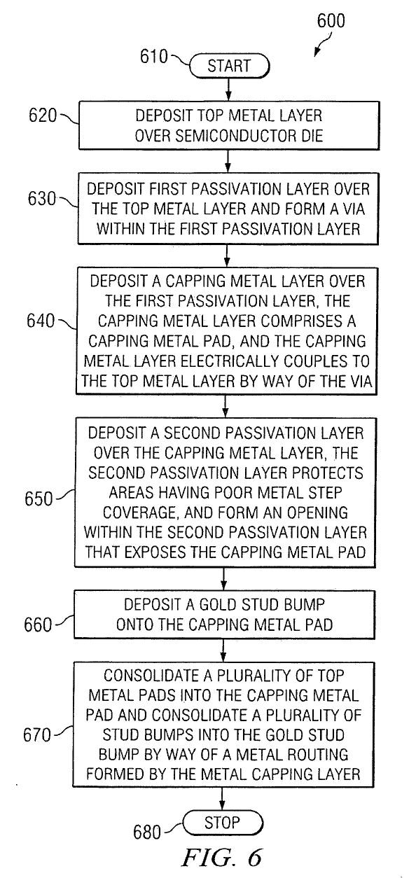

FIG. 6 shows an exemplary flow diagram 600 according to various embodiments. The method starts (block 610) and proceeds to depositing a top metal layer over a semiconductor die (block 620). Thereafter, a first passivation layer is deposited over the top metal layer, and a via is formed within the first passivation layer (block 630). A capping metal layer is then deposited over the first passivation layer (block 640). The capping metal layer comprises a capping metal pad, and the capping metal layer electrically couples to the top metal layer by way of the via. A second passivation layer is deposited over the capping metal layer, and an opening is formed in the second passivation layer that exposes the capping metal pad (block 650). Any thinning of the capping metal layer that may occur due to poor step coverage is protected by the second passivation layer and potentially poor electromigration effects are reduced. A stud bump is then deposited onto the capping metal pad (block 660). In some embodiments, the stud bump is a gold stud bump. The stud bump is thus deposited over passivation and is not constrained to placement on pads within a pad ring disposed along a periphery of a die. Thereafter, a plurality of top metal pads are consolidated into the capping metal pad and a plurality of stud bumps are consolidated into a single stud bump (block 670). The consolidating is accomplished by way of a metal routing that is formed by the metal capping layer. Such consolidation increases the bump-to-BGA ball ratio and reduces a package ball count. Thus, the conserved BGA balls can be put to other uses (e.g., other power or I/O signals). The method then ends (block 680).

The above discussion is meant to be illustrative of the principles and various embodiments of the present invention. Numerous variations and modifications will become apparent to those skilled in the art once the above disclosure is fully appreciated. For example, in some embodiments, the die 110 may be electrically coupled to a circuit board or other type of carrier or package by way of the electrically conductive bumps 130. Also, in some instances, a non-conductive under-filling is used to fill open spaces between the die 110 and the substrate 140. Further, unless otherwise indicated, any one or more of the layers set forth herein can be formed in any number of suitable ways (e.g., with spin-on techniques, sputtering techniques (e.g., magnetron and/or ion beam sputtering), thermal growth techniques, deposition techniques such as chemical vapor deposition (CVD), physical vapor deposition (PVD) and/or plasma enhanced chemical vapor deposition (PECVD), or atomic layer deposition (ALD)). And, unless otherwise indicated, any one or more of the layers can be patterned in any suitable manner (e.g., via lithographic and/or etching techniques). It is intended that the following claims be interpreted to embrace all such variations and modifications.

What is claimed is:

1. A method comprising:
depositing a first passivation layer over a semiconductor die;
depositing a capping metal layer over the first passivation layer, the capping metal layer comprises a capping metal pad; and
depositing a stud bump onto the capping metal pad.

2. The method according to claim 1 wherein depositing the stud bump further comprises depositing a gold stud bump.

3. The method according to claim 1 further comprising depositing a top metal layer over the semiconductor die prior to depositing the first passivation layer.

4. The method according to claim 3 further comprising forming a via within the first passivation layer.

5. The method according to claim 4 wherein depositing the capping metal layer further comprises depositing the capping metal layer, wherein the capping metal layer electrically couples to the top metal layer by way of the via.

6. The method according to claim 1 further comprising depositing a second passivation layer over the capping metal layer.

7. The method according to claim 6 further comprising forming an opening within the second passivation layer to expose the capping metal pad.

8. The method according to claim 6 further comprising protecting areas with poor metal step coverage by way of the second passivation layer.

9. The method according to claim 1 further comprising consolidating a plurality of top metal pads into the capping metal pad by way of a metal routing formed by the capping metal layer.

10. The method according to claim 1 further comprising consolidating a plurality of stud bumps into a single stud bump by way of a metal routing formed by the capping metal layer.

11. A semiconductor device comprising:
a first passivation layer;
a capping metal layer on the first passivation layer, the capping metal layer comprising a capping metal pad; and
a stud bump on the capping metal pad.

12. The semiconductor device according to claim 11 wherein the stud bump comprises a gold stud bump.

13. The semiconductor device according to claim 11 further comprising a top metal layer, wherein the first passivation layer is on the top metal layer.

14. The semiconductor device according to claim 13 wherein the top metal layer comprises a top metal pad.

15. The semiconductor device according to claim 13 wherein the top metal layer comprises a top metal routing.

16. The semiconductor device according to claim 13 wherein the first passivation layer comprises a via, and wherein the capping metal layer electrically couples to the top metal layer by way of the via.

17. The semiconductor device according to claim 11 further comprising a second passivation layer on the capping metal layer.

18. The semiconductor device according to claim 16 further comprising a second passivation layer on the via, wherein the second passivation layer protects the semiconductor device from electromigration.

19. The semiconductor device according to claim 17 wherein the second passivation layer further comprises an opening that exposes the capping metal pad.

20. The semiconductor device according to claim 11 further comprising a metal routing formed by the capping layer, wherein the metal routing is used to consolidate top metal pads disposed along a periphery of a die.

21. The semiconductor device according to claim 11 further comprising a first power distribution grid, a second power distribution grid, and a plurality of vias, wherein the first power distribution grid electrically couples to the second power distribution grid by way of the plurality of vias.

22. The semiconductor device according to claim 11 wherein the capping metal pad further comprises one or more selected from the group consisting of: a bump region, and a probe region.
